(19) United States
(12) Patent Application Publication
(10) Pub. No.: US 2022/0085789 A1
(43) Pub. Date: Mar. 17, 2022

(54) INTEGRATED STRUCTURE OF CRYSTAL RESONATOR AND CONTROL CIRCUIT AND INTEGRATION METHOD THEREFOR

(71) Applicant: NINGBO SEMICONDUCTOR INTERNATIONAL CORPORATION (SHANGHAI BRANCH), Shinghai (CN)

(72) Inventor: Xiaoshan QIN, Zhejiang (CN)

(21) Appl. No.: 17/419,617

(22) PCT Filed: Nov. 5, 2019
(86) PCT No.: PCT/CN2019/115646

§ 371 Date: Jun. 29, 2021

(30) Foreign Application Priority Data
Dec. 29, 2018 (CN) 201811643176.3

(51) Int. Cl. H03H 9/17; H03H 9/13; H03H 3/007

(52) U.S. Cl. CPC H03H 9/17; H03H 3/007; H03H 9/13

(57) ABSTRACT

An integrated structure of crystal resonator and control circuit and an integration method therefor. The crystal resonator is formed by first forming the lower cavity (120) in the device wafer (100) containing the control circuit (110), forming the piezoelectric vibrator (200) on the device wafer (100) and then enclosing the piezoelectric vibrator (200) within the upper cavity (400) through forming the cap layer (420) using a planar fabrication process. In addition, a semiconductor die (500) is bonded to the same device wafer (100), helping in enhancing device performance by allowing on-chip modulation of the crystal resonator's parameters. In this way, in addition to being able to integrate with other semiconductor components more easily with a higher degree of integration, the crystal resonator is more compact in size and less power-consuming.

### TECHNICAL FIELD

The present invention relates to the technical field of semiconductor and, in particular, to an integrated structure of crystal resonator and control circuit and an integration method therefor.

### BACKGROUND

A crystal resonator is a device operating on the basis of inverse piezoelectricity of a piezoelectric crystal. As key components in crystal oscillators and filters, crystal resonators have been widely used to create high-frequency electrical signals for performing precise timing, frequency referencing, filtering and other frequency control functions that are necessary for measurement and signal processing systems.

The continuous development of semiconductor technology and increasing popularity of integrated circuits has brought about a trend toward miniaturization of various semiconductor components. However, it is difficult to integrate existing crystal resonators with other semiconductor components, and also the sizes of the existing crystal resonators are relatively large.

For example, commonly used existing crystal resonators include surface-mount ones, in which a base is bonded with a metal solder (or an adhesive) to a cover to form a hermetic chamber in which a piezoelectric vibrator is housed. In addition, electrodes for the piezoelectric vibrator are electrically connected to an associated circuit via solder pads or wires. Further shrinkage of such crystal resonators is difficult, and their electrical connection to the associated circuit by soldering or gluing additionally hinders their miniaturization.

### SUMMARY OF THE INVENTION

It is an object of the present invention to provide a method for integrating a crystal resonator with a control circuit, which overcomes the above described problems with conventional crystal resonators, i.e., a bulky size and difficult integration.

To solve the problem, the present invention provides a method for integrating a crystal resonator with a control circuit, comprising:

providing a device wafer in which the control circuit is formed, and etching the device wafer to form a lower cavity for the crystal resonator;

forming a piezoelectric vibrator comprising a top electrode, a piezoelectric crystal and a bottom electrode on a front side of the device wafer above the lower cavity and forming a first connecting structure electrically connecting the top and bottom electrodes of the piezoelectric vibrator to the control circuit;

forming a cap layer on the front side of the device wafer, wherein the cap layer covers the piezoelectric vibrator, and the cap layer together with the piezoelectric vibrator and the device wafer delimits an upper cavity for the crystal resonator;

forming a second connecting structure in the device wafer and bonding a semiconductor die to the device wafer so that the second connecting structure connects the semiconductor die to the control circuit.

It is a further object of the present invention to provide an integrated structure of a crystal resonator and a control circuit, comprising:

a device wafer in which the control circuit and a lower cavity are formed, wherein the lower cavity is exposed at a front side of the device wafer;

a piezoelectric vibrator comprising a top electrode, a piezoelectric crystal and a bottom electrode, wherein the piezoelectric vibrator is formed on the front side of the device wafer above the lower cavity;

a first connecting structure configured to electrically connect the top and bottom electrodes of the piezoelectric vibrator to the control circuit;

a cap layer which is formed on the front side of the device wafer and covers the piezoelectric vibrator, wherein the cap layer together with the piezoelectric vibrator and the device wafer delimits an upper cavity;

a semiconductor die bonded to the device wafer; and

a second connecting structure configured to electrically connect the semiconductor die to the control circuit.

In the method of the present invention, the crystal resonator and the control circuit are integrated on the same device wafer, which is accomplished by first forming the lower cavity in the device wafer containing the control circuit using a planar fabrication process, forming the piezoelectric vibrator on the device wafer and then enclosing the piezoelectric vibrator within the upper cavity through forming the cap layer using another planar fabrication process. Additionally, the semiconductor die can be further bonded to the device wafer, resulting in an enhancement in performance of the crystal resonator by allowing on-chip modulation of its parameters (e.g., in order to correct raw deviations of the crystal resonator such as temperature and frequency drifts), in addition to a significant increase in the crystal resonator's degree of integration.

As such, compared with traditional crystal resonators (e.g., surface-mount ones), in addition to being able to integrate with other semiconductor components with a higher degree of integration, the crystal resonator proposed in the present invention is more compact or miniaturized in size and hence less costly and less power-consuming.

### BRIEF DESCRIPTION OF THE DRAWINGS

FIG. 1 shows a flowchart schematically illustrating a method for integrating a crystal resonator with a control circuit according to an embodiment of the present invention.

FIGS. 2a to 2k are schematic representations of structures resulting from steps in a method for integrating a crystal resonator with a control circuit according to an embodiment of the present invention.

In these figures,

100 denotes a device wafer; AA, a device area; 100A, a substrate wafer; 100B, a dielectric layer; 110, a control circuit; 111, a first circuit; 111a, a first interconnecting structure; 111b, a third interconnecting structure; 112, a second circuit; 112a, a second interconnecting structure; 112b, a fourth interconnecting structure; 120, a lower cavity; 200, a piezoelectric vibrator; 210, a bottom electrode; 220, a piezoelectric crystal; 230, a top electrode; 300, an encapsulation layer; 300a, a through hole; 310, a conductive plug; 320, a rewiring layer; 400, an upper cavity; 410, a sacrificial layer; 420, a cap layer; 420a, an opening; 430, a closure plug; 500, a semiconductor die; 511, a first contact pad; 512, a second contact pad; and 600, an encapsulation layer.

### DETAILED DESCRIPTION

The core idea of the present invention is to provide an integrated structure of a crystal resonator and a control circuit and an integration method therefor, in which planar fabrication processes are utilized to integrate the crystal resonator and the a semiconductor die both onto a device wafer where the control circuit is formed. This, on the one hand, results in a size reduction of the crystal resonator and, on the other hand, allows an increased degree of integration of the crystal resonator with other semiconductor components.

Specific embodiments of the structure and method proposed in the present invention will be described below in greater detail with reference to the accompanying drawings. Features and advantages of the invention will be more apparent from the following description. Note that the accompanying drawings are provided in a very simplified form not necessarily drawn to exact scale, and their only intention is to facilitate convenience and clarity in explaining the disclosed embodiments.

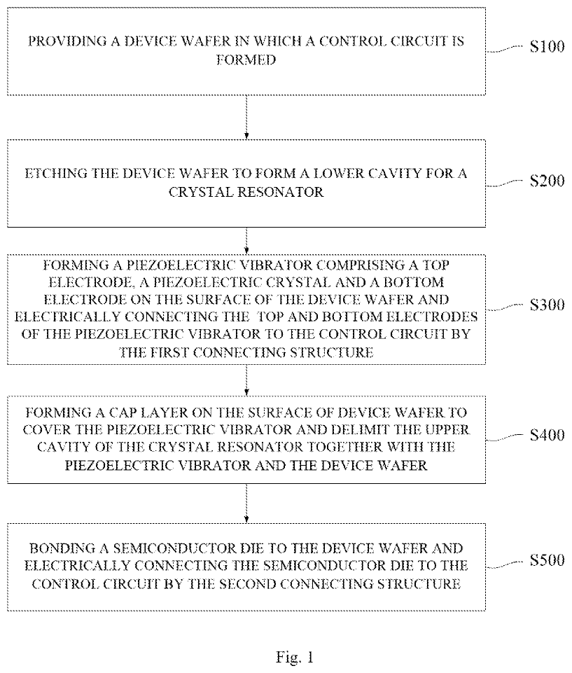

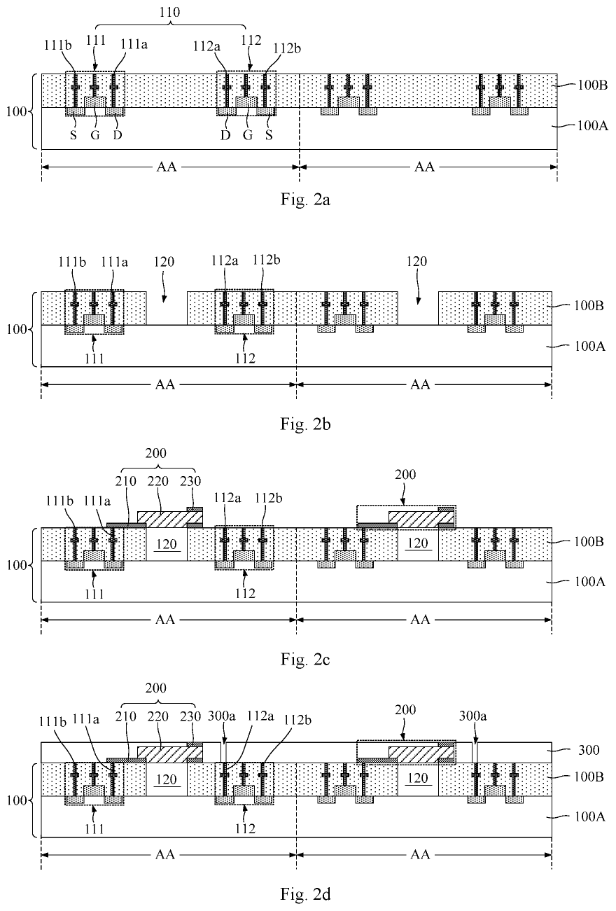

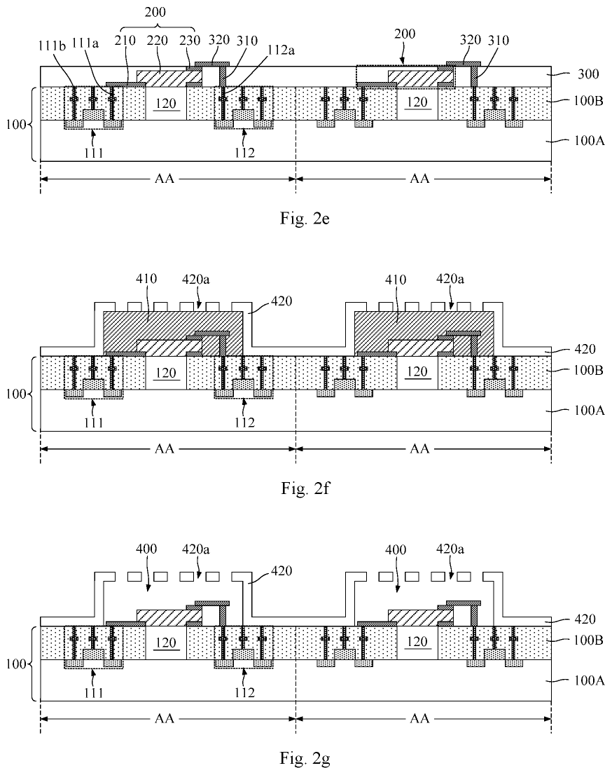

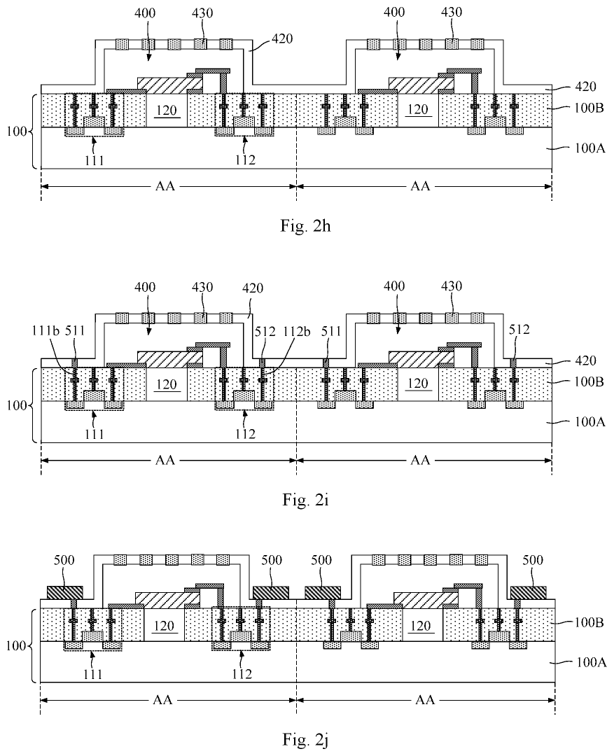

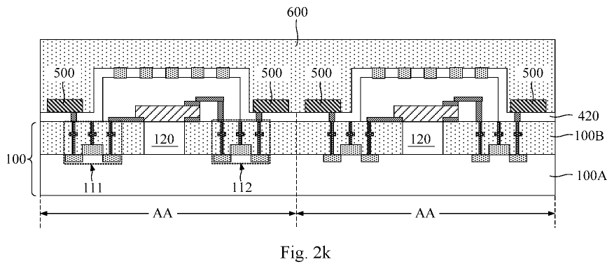

FIG. 1 shows a flowchart schematically illustrating a method for integrating a crystal resonator with a control circuit according to an embodiment of the present invention, and FIGS. 2a to 2k are schematic representations of structures resulting from steps in the method for integrating a crystal resonator with a control circuit according to an embodiment of the present invention. In the following, steps for forming the crystal resonator will be described in detail with reference to the figures.

In step S100, with reference to FIG. 2a, a device wafer 100 is provided, in which a control circuit 110 is formed.

In this embodiment, the control circuit 110 includes a plurality of interconnecting structures, at least some of which extend to a surface of the device wafer. Specifically, the interconnecting structures in the control circuit 110 are configured for subsequent electrical connection with a semiconductor die and a piezoelectric vibrator.

A plurality of crystal resonators may be formed on the single device wafer 100. Accordingly, there may be a plurality of device areas AA defined in the device wafer 100, with the control circuit 110 being formed in a corresponding one of the device areas AA.

The control circuit 110 may include a first circuit 111 and a second circuit 112. In this embodiment, the first and second circuits 111, 112 are configured for electrical connection with a bottom electrode and a top electrode of the subsequently formed piezoelectric vibrator, respectively.

With continued reference to FIG. 2a, the first circuit 111 may include a first transistor, a first interconnecting structure 111a and a third interconnecting structure 111b. The first transistor may be buried within the device wafer 100, and the first and third interconnecting structures 111a, 111b may be both connected to the first transistor and extend to the surface of the device wafer 100. The first interconnecting structure 111a may be connected, for example, to a drain of the first transistor, and the third interconnecting structure 111b, for example, to a source of the first transistor.

Similarly, the second circuit 112 may include a second transistor, a second interconnecting structure 112a and a fourth interconnecting structure 112b. The second transistor may be buried within the device wafer 100, and the second and fourth interconnecting structures 112a, 112b may be both connected to the second transistor and extend to the surface of the device wafer 100. The second interconnecting structure 112a may be connected, for example, to a drain of the second transistor, and the fourth interconnecting structure 112b, for example, to a source of the second transistor.

A method for forming the control circuit 110 may include:

providing a substrate wafer 100A and forming the first and second transistors 111T, 112T on the substrate wafer 100A; and

then forming a dielectric layer 100B on the substrate wafer 100A to cover the first and second transistors 111T, 112T, and forming the third, first, fourth and second interconnecting structures 111b, 111a, 112a, 112b in the dielectric layer 100B, resulting in the formation of the device wafer 100.

In other words, the device wafer 100 includes the substrate wafer 100A and the dielectric layer 100B formed thereon, and the first and second transistors are both formed on the substrate wafer 100A. Additionally, the dielectric layer 100B covers the first and second transistors, and the third, first, fourth and second interconnecting structures 111b, 111a, 112a, 112b are all so formed in the dielectric layer 100B as to extend to the surface of the dielectric layer 100B.

The substrate wafer 100A may be either a silicon wafer or a silicon-on-insulator (SOI) wafer. In the latter case, the substrate wafer may include a base layer, a buried oxide layer and a top silicon layer, which are sequentially stacked in this order in the direction from a back side 100D to a front side 100U.

In step S200, with reference to FIG. 2b, the device wafer 100 is etched so that a lower cavity 120 for the crystal resonator is formed therein, and the lower cavity 120 is exposed at the front side of the device wafer. The lower cavity 120 is formed to provide a space in which the subsequently formed piezoelectric vibrator can vibrate.

In this embodiment, the lower cavity 120 is formed in the dielectric layer 100B of the device wafer. In each device area AA, such a lower cavity 120 may be formed. A method for forming the lower cavity 120 may include etching the dielectric layer 100B until the substrate wafer 100A is reached. In this manner, the lower cavity 120 may be formed in the dielectric layer 100B. The lower cavity 120 may have a depth that is determined, without limitation, as practically required. For example, the lower cavity 120 may either extend only in the dielectric layer 100B or further into the substrate wafer 100A from the dielectric layer 100B.

As noted above, the substrate wafer 100A may be implemented as an SOI wafer. In this case, the etching process for forming the lower cavity may proceed further through a top silicon layer and partially a buried oxide layer of the SOI wafer so that the formed lower cavity extends from the dielectric layer down into the buried oxide layer.

It is to be noted that the relative positions of the lower cavity 120 and the first and second circuits shown in the figures are merely for illustration, and in practice, the arrangement of the first and second circuits may depend on the actual circuit lay-out requirements. The present invention is not limited in this regard.

In step S300, with reference to FIGS. 2c to 2e, a piezoelectric vibrator 200 including a top electrode 230, a piezoelectric crystal 220 and a bottom electrode 210 is formed on the front side of the device wafer 100 above the lower cavity 120, and a first connecting structure is formed to electrically connect both the top and bottom electrodes 230, 210 of the piezoelectric vibrator 200 to the control circuit.

It will be appreciated that, in this embodiment, the bottom electrode 210 is electrically connected to the first circuit 111 (more exactly, the first interconnecting structure 111a therein) and the top electrode 230 to the second circuit 112 (more exactly, the second interconnecting structure 112a therein). As such, an electrical signal can be applied by the control circuit 110 to the bottom and top electrodes 210, 230 of the piezoelectric vibrator 200 to create an electric field therebetween, which causes the piezoelectric crystal 220 of the piezoelectric vibrator 200 to change its shape. When the electric field in the piezoelectric vibrator 200 is inverted, the piezoelectric crystal 220 will change its shape in the opposite direction. Therefore, when the control circuit 120 applies an AC signal to the piezoelectric vibrator 200, the piezoelectric vibrator 200 will change shape alternately in opposite directions and thus alternately contract and expand due to a change in direction of the electric field. As a result, the piezoelectric vibrator 200 will vibrate mechanically.

Specifically, the formation of the piezoelectric vibrator 200 may include, for example, the steps as follows:

Step 1: Forming the bottom electrode 210 at a predetermined location on the surface of the device wafer 100, as shown in FIG. 2c. In this embodiment, the bottom electrode 210 surrounds the lower cavity 120 and is electrically connected to the first interconnecting structure 111a of the control circuit and thus to the first transistor. This enables the first transistor to control an electrical signal applied to the bottom electrode 210.

Notably, in this embodiment, the bottom electrode 210 covers the first interconnecting structure 111a but not the third interconnecting structure. The bottom electrode 210 also does not cover the fourth and second interconnecting structures.

The bottom electrode 210 may be formed of, for example, silver, and the formation may involve successive processes of thin-film deposition, photolithography and etching. Alternatively, the bottom electrode 210 may be formed using a vapor deposition process.

Step 2: Bonding the piezoelectric crystal 220 to the bottom electrode 210, as shown in FIG. 2c, so that the piezoelectric crystal 220 is located above the lower cavity 120, with its peripheral edge portions residing on the bottom electrode. As such, part of the piezoelectric crystal 220 is in positional correspondence with the lower cavity 120. The piezoelectric crystal 220 may be, for example, a quartz crystal plate.

Step 3: Forming the top electrode 230 on the piezoelectric crystal 220, as shown in FIG. 2c. Similar to the bottom electrode 210, the top electrode 230 may also be formed of, for example, silver, using a thin-film deposition process or vapor deposition process. The top electrode 230 may be brought into electrical connection with the control circuit in a subsequent process.

It is to be noted that, in this embodiment, the bottom electrode 210, the piezoelectric crystal 220 and the top electrode 230 are successively formed over the device wafer 100 using semiconductor processes. However, in other embodiments, it is also possible to form the top and bottom electrodes on opposing sides of the piezoelectric crystal and then bond the three as a whole onto the device wafer.

As noted above, in the resulting piezoelectric vibrator 200, the top and bottom electrodes 230, 210 are electrically connected to the second and first interconnecting structures 112a, 111a by the first connecting structure.

Specifically, the first connecting structure may include a first connecting member that connects the first interconnecting structure 111a to the bottom electrode 210 of the piezoelectric vibrator and a second connecting member that connects the second interconnecting structure 112a to the top electrode 230 of the piezoelectric vibrator.

In this embodiment, the bottom electrode 210 is formed on the surface of the device wafer 100 and under the piezoelectric crystal 220 and has an extension extending beyond the piezoelectric crystal 220 thereunder over the first interconnecting structure 111a. Therefore, it can be considered that the extension of the bottom electrode 210 forms the first connecting member.

Of course, in other embodiments, it is also possible that the first connecting member is so formed on the device wafer 100 as to be electrically connected to the first interconnecting structure prior to the formation of the bottom electrode and brought into electrical connection with the bottom electrode 210 subsequent to the formation of the bottom electrode. In this case, the first connecting member may include, for example, a rewiring layer, which is connected to the first interconnecting structure and is brought into electrical connection with the bottom electrode 210 subsequent to the formation of the bottom electrode on the device wafer.

Subsequent to the formation of the top electrode 230, the second connecting member may be formed to electrically connect the top electrode 230 to the second interconnecting structure 112a. The second connecting member may be comprised of an interconnecting wire and a conductive plug. The conductive plug may be connected at the bottom to the second interconnecting structure and at the top to one end of the interconnecting wire, and the other end of the interconnecting wire may cover at least part of, and thus come into connection with, the top electrode 230. Specifically, the formation of the second connecting member may include the steps below.

At first, with reference to FIG. 2d, an encapsulation layer 300 is formed on the device wafer 100. In this embodiment, the encapsulation layer 300 covers the piezoelectric crystal 220, with the top electrode 230 being exposed from the encapsulation layer. Exemplary materials for the encapsulation layer 300 may include polyimide.

Next, with continued reference to FIG. 2d, a through hole 300a is formed in the encapsulation layer 300. In this embodiment, the through hole 300a extends through the encapsulation layer 300 up to the device wafer so that the second interconnecting structure 112a is exposed therein.

Subsequently, with reference to FIG. 2e, a conductive material is filled in the through hole 300a, resulting in the formation of the conductive plug 310, which is electrically connected to the second interconnecting structure 112a at the bottom and exposed from the encapsulation layer 300 at the top.

Afterward, with continued reference to FIG. 2e, an interconnecting wire 320 is formed on the encapsulation layer 300 and covers the top electrode 230 at one end and covers the conductive plug 310 at the other end, and the encapsulation layer 300 is then removed so that the top electrode 230 is connected to the second circuit 112a via the interconnecting wire 320 and the conductive plug 310.

Of course, in alternative embodiments, the top electrode may be so formed on the piezoelectric crystal as to have an extension extending beyond the piezoelectric crystal. In this case, the conductive plug of the second connecting member may be so formed under the extension of the top electrode that it is connected to the second interconnecting structure at the bottom and connected to, and thus provides support for, the extension of the top electrode at the top.

Alternatively, the conductive plug of the second connecting member may be formed prior to the formation of the top electrode. Specifically, the formation of the top electrode and the conductive plug of the second connecting member may include the steps below.

At first, an encapsulation layer is formed on the device wafer 100. In this embodiment, the encapsulation layer covers the device wafer 100, with the piezoelectric crystal 220 being exposed therefrom.

Next, a through hole is formed in the encapsulation layer and a conductive material is filled in the through hole, resulting in the formation of the conductive plug which is electrically connected to the second interconnecting structure 112a.

Afterward, the top electrode is formed on the piezoelectric crystal 220 so that it covers at least part of the piezoelectric crystal 220 and extends beyond the piezoelectric crystal 220 over the conductive plug. As a result, the top electrode is electrically connected to the second interconnecting structure 112a via the conductive plug 310.

In step S400, with reference to FIGS. 2f to 2g, a cap layer 420 is formed on the front side of the device wafer 100 and covers the piezoelectric vibrator 200 and delimits an upper cavity 400 of the crystal resonator together with the piezoelectric vibrator 200 and the device wafer 100.

In this way, the piezoelectric vibrator 200 is enclosed in the upper cavity 400 and can vibrate in the lower and upper cavities 120, 400.

Specifically, the formation of the cap layer 420 that delimits the upper cavity 400 may include, for example, the steps below.

In a first step, with reference to FIG. 2f, a sacrificial layer 410 is formed on the surface of the device wafer 100 and covers the piezoelectric vibrator 200.

In a second step, with continued reference to FIG. 2f, a cap material layer is formed over the surface of the device wafer 100 and wraps the sacrificial layer 410 by covering its top and side surfaces. In this embodiment, the cap material layer also covers the surface of the device wafer.

The space occupied by the sacrificial layer 410 corresponds to the internal space of the subsequently formed upper cavity. Therefore, a depth of the upper cavity to be formed may be adjusted by changing a height of the sacrificial layer. It will be recognized that the depth of the upper cavity may be determined as practically required, and the present invention is not limited in this regard.

In a third step, with reference to FIG. 2g, at least one opening 420a is formed in the cap material layer, thus resulting in the formation of the cap layer 420. The sacrificial layer 410 is exposed in the opening 420a.

In a fourth step, with continued reference to FIG. 2g, the sacrificial layer 410 is removed via the opening 420a, resulting in the formation of the upper cavity 400.

In this embodiment, the cap layer 420 further covers the surface of the device wafer 100 and thus the third and fourth interconnecting structures 111b, 112b of the control circuit. It is to be noted that the third and fourth interconnecting structures 111b, 112b in the control circuit are subsequently brought into connection with a semiconductor die.

Optionally, with reference to FIG. 2h, the method may further include closing the opening in the cap layer 420, so as to close the upper cavity, thus enclosing the piezoelectric vibrator within the upper cavity 400. Specifically, the enclosure of the upper cavity 400 can be accomplished by closing the opening with a closure plug 430.

In step S500, with reference to FIGS. 2i and 2j, a semiconductor die 500 is bonded to the front side of the device wafer 100 in such a manner that it is electrically connected to the control circuit by a second connecting structure.

In the semiconductor die, for example, a drive circuit for providing an electrical signal may be formed. The electrical signal is applied by the control circuit to the piezoelectric vibrator 200 so as to control shape change thereof.

The second connecting structure may be formed prior to the formation of the semiconductor die, and the formation may include forming contact pads on the front side of the device wafer to electrically connect to the control circuit at the bottom and to the semiconductor die at the top.

In this embodiment, the cap layer 420 also extends over the surface of the device wafer. Thus, it will be appreciated that the contact pads are formed within, and penetrate through, the cap layer 420, and the semiconductor die 500 is bonded to the cap layer 420.

Specifically, the formation of the contact pad in the second connecting structure may include the steps below.

At first, openings are formed in the cap layer 420 overlying the surface of the device wafer. In this embodiment, openings are formed respectively above the third and fourth interconnecting structures 111b, 112b so that these interconnecting structures are exposed in the respective openings.

Next, the contact pads are formed by filling a conductive material in the openings. In this embodiment, a first contact pad 511 and a second contact pad 512 are formed. The first contact pad 511 is electrically connected to the third interconnecting structure 111b at the bottom and configured for electrical connection with the semiconductor die 500 at the top. The second contact pad 512 is electrically connected to the fourth interconnecting structure 112b at the bottom and configured for electrical connection with the semiconductor die 500 at the top.

The semiconductor die 500 may be heterogeneous from the device wafer 100. That is, the semiconductor die 500 may include a substrate made of a material different from that of the device wafer 100. For example, in this embodiment, differing from the device wafer 100 that is made of silicon, the substrate of the heterogeneous die may be formed of a Group III-V semiconductor material or a Group II-VI semiconductor material (specific examples include germanium, germanium silicon, gallium arsenide, etc.)

Optionally, with reference to FIG. 2k, an encapsulation layer 600 may be formed over the device wafer 100, and cover the semiconductor die 500 and an external surface of the cap layer 420 outside the upper cavity.

It will be appreciated that the encapsulation layer 600 is provided to cover the entire surface of the device wafer and thus enclose and protect all the underlying structures. Exemplary materials for the encapsulation layer 600 may include photoresist.

A structure for integrating a crystal resonator with a control circuit corresponding to the above method will be described below with reference to FIGS. 2a to 2k. The integrated structure of the crystal resonator and the control circuit includes:

a device wafer 100, in which the control circuit and a lower cavity 120 are formed, the lower cavity 120 exposed at a front side of the device wafer (in this embodiment, the control circuit comprises interconnecting structures, at least some of which extend to the front side of the device wafer 100);

a piezoelectric vibrator 200 comprising a top electrode 230, a piezoelectric crystal 220 and a bottom electrode 210, the piezoelectric vibrator 200 formed on the front side of the device wafer 100 above the lower cavity and in positional correspondence with the lower cavity (in this embodiment, the piezoelectric vibrator 200 has peripheral edge portions residing on side walls of the lower cavity 120);

a first connecting structure configured to electrically connect the top and bottom electrodes 230, 210 of the piezoelectric vibrator 200 to the control circuit;

a cap layer 420 formed on the front side of the device wafer 100 so as to enclose the piezoelectric vibrator 200 and delimit an upper cavity 400 together with the piezoelectric vibrator 200 and the device wafer 100;

a semiconductor die 500 bonded to a front side of the device wafer 100, wherein in the semiconductor die, there is formed, for example, a drive circuit for producing an electrical signal to be transmitted to the piezoelectric vibrator 200 via the control circuit 100; and

a second connecting structure configured to electrically connect the semiconductor die 500 to the control circuit.

The semiconductor die 500 may be heterogeneous from the device wafer 100. That is, the semiconductor die 500 may include a substrate made of a material different from that of the device wafer 100. For example, in this embodiment, differing from the device wafer 100 that is made of silicon, the substrate of the heterogeneous die may be formed of a Group III-V semiconductor material or a Group II-VI semiconductor material (specific examples include germanium, germanium silicon, gallium arsenide, etc.)

In this way, integration of the crystal resonator with the control circuit can be accomplished on a single device wafer by forming the lower cavity 120 in the device wafer 100 and fabricating the cap layer 420 using semiconductor processes to enclose the piezoelectric vibrator 200 within the upper cavity 400 and thus ensures that the piezoelectric vibrator 200 can oscillate within the upper and lower cavities 400, 120. In addition, the semiconductor die 500 is bonded to the device wafer 100 so that performance of the crystal resonator can be enhanced by on-chip modulation under the control of the control circuit 110 for correcting raw deviations of the crystal resonator such as temperature and frequency drifts. Therefore, in addition to an enhanced degree of integration, the crystal resonator of the present invention fabricated using the semiconductor processes is more compact in size and thus less power-consuming.

With continued reference to FIG. 2a, the control circuit may include a first circuit 111 and a second circuit 112, which may be electrically connected to the top and bottom electrodes of the piezoelectric vibrator 200, respectively.

Specifically, the first circuit 111 may include a first transistor, a first interconnecting structure 111a and a third interconnecting structure 111b. The first transistor may be buried within the device wafer 100, and the first and third interconnecting structures 111a, 111b may be both connected to the first transistor and extend to the surface of the device wafer 100. The first interconnecting structure 111a may be electrically connected to the bottom electrode 210, and the third interconnecting structure 111b may be electrically connected to the semiconductor die.

Similarly, the second circuit 112 may include a second transistor, a second interconnecting structure 112a and a fourth interconnecting structure 112b. The second transistor may be buried within the device wafer 100, and the second and fourth interconnecting structures 112a, 112b may be both connected to the second transistor and extend to the surface of the device wafer 100. The second interconnecting structure 112a may be electrically connected to the top electrode 230 and the fourth interconnecting structure 112b to the semiconductor die.

In addition, the first connecting structure may include a first connecting member that connects the first interconnecting structure 111a to the bottom electrode 210 of the piezoelectric vibrator and a second connecting member that connects the second interconnecting structure 112a to the top electrode 230 of the piezoelectric vibrator.

In this embodiment, the bottom electrode 210 is formed on the surface of the device wafer 100 around the lower cavity 120 and has an extension extending laterally beyond the piezoelectric crystal 220. Additionally, the extension of the bottom electrode covers the first interconnecting structure 111a in the first circuit 111 so as to bring the bottom electrode 210 into electrical connection with the first interconnecting structure 111a in the first circuit 111. Therefore, it can be considered that the extension of the bottom electrode forms the first connecting member.

Further, the top electrode 230 is formed on the piezoelectric crystal 220 and is electrically connected to the second interconnecting structure 112a in the second circuit 112 via the second connecting member.

Specifically, the second connecting member that connects the top electrode 230 to the second circuit 112 may include a conductive plug and an interconnecting wire. The conductive plug may be formed on the surface of the device wafer 100 in such a manner that it is connected to the second interconnecting structure 112a at the bottom. The interconnecting wire may cover the top electrode 230 at one end and cover at least part of, and thus come into connection with, the conductive plug at the other end. In this way, it will be recognized that the conductive plug also serves to support the interconnecting wire.

In alternative embodiments, the second connecting member may include only the conductive plug. In this case, the conductive plug may be electrically connected to the top electrode 230 at one end and to the second interconnecting structure 112a at the other end. For example, the top electrode may extend from the piezoelectric crystal over the end of the conductive plug.

With continued reference to FIG. 2k, in this embodiment, the cap layer 420 further extends from side walls of the upper cavity 120 over the surface of the device wafer 100 and the semiconductor die 500 is bonded to the cap layer 420. Additionally, the second connecting structure includes contact pads formed in the cap layer 420, which are electrically connected to the control circuit at the bottom and to the semiconductor die 500 at the top.

In this embodiment, the contact pads in the second connecting structure include a first contact pad 511 and a second contact pad 512. The first contact pad 511 is electrically connected to the third interconnecting structure 111b at the bottom and to the semiconductor die 500 at the top, and the second contact pad 512 is electrically connected to the fourth interconnecting structure 112b at the bottom and to the semiconductor die 500 at the top.

With continued reference to FIG. 2k, in this embodiment, at least one opening is formed in a portion of the cap layer 400 in positional correspondence with the upper cavity, and a closure plug 430 is filled in the opening. In this way the upper cavity 400 is closed, thus enclosing the piezoelectric vibrator 200 within the upper cavity 400.

Further, with continued reference to FIG. 2a, in this embodiment, the device wafer 100 includes a substrate wafer 100A and a dielectric layer 100B. The first and second transistors may be both formed on the substrate wafer 100A, and the dielectric layer 100B may be formed on the substrate wafer 100A and cover both the first and second transistors. Each of the third, first, fourth and second interconnecting structures may be formed in the dielectric layer 100B such as to extend to a surface of the dielectric layer 100B.

The crystal resonator may further include an encapsulation layer 600 formed on the device wafer 100, and the encapsulation layer 600 covers both the semiconductor die and an external surface of the cap layer 420 outside the upper cavity. In other words, the encapsulation layer 600 covers all the structures formed on the device wafer, thus providing protection to these underlying structures. It can be considered that the crystal resonator is packaged with the encapsulation layer 600.

In summary, in the method for integrating the crystal resonator with the control circuit according to the present invention, the integration of the crystal resonator with the control circuit is accomplished by first forming the lower cavity in the device wafer containing the control circuit, forming the piezoelectric vibrator on the device wafer and then enclosing the piezoelectric vibrator within the upper cavity through forming the cap layer using a planar fabrication process. Additionally, for example, the semiconductor die containing the drive circuit may be further bonded to the device wafer. In other words, the semiconductor die, control circuit and crystal resonator may be integrated on the same device wafer. This is favorable to on-chip modulation for correcting raw deviations of the crystal resonator such as temperature and frequency drifts. compared with traditional crystal resonators (e.g., surface-mount ones), in addition to being able to integrate with other semiconductor components more easily with a higher degree of integration, the crystal resonator of the present invention that is fabricated using planar fabrication processes is more compact in size and hence less power-consuming.

The description presented above is merely that of a few preferred embodiments of the present invention without limiting the scope thereof in any sense. Any and all changes and modifications made by those of ordinary skill in the art based on the above teachings fall within the scope as defined in the appended claims.

1. A method for integrating a crystal resonator with a control circuit, comprising:
providing a device wafer in which a control circuit is formed, and etching the device wafer to form a lower cavity for the crystal resonator;
forming a piezoelectric vibrator comprising a top electrode, a piezoelectric crystal and a bottom electrode on a front side of the device wafer above the lower cavity, and forming a first connecting structure electrically connecting the top electrode and the bottom electrode of the piezoelectric vibrator to the control circuit;
forming a cap layer on the front side of the device wafer, wherein the cap layer covers the piezoelectric vibrator, and the cap layer together with the piezoelectric vibrator and the device wafer delimits an upper cavity for the crystal resonator; and
bonding a semiconductor die to the front side of the device wafer and forming a second connecting structure electrically connecting the semiconductor die to the control circuit.

2. The method for integrating a crystal resonator with a control circuit according to claim 1, wherein the device wafer comprises a substrate wafer and a dielectric layer formed on the substrate wafer, and wherein the lower cavity is formed in the dielectric layer.

3. The method for integrating a crystal resonator with a control circuit according to claim 2, wherein the substrate wafer is a silicon-on-insulator substrate comprising a base layer, a buried oxide layer and a top silicon layer, which are sequentially stacked from a back side to the front side of the substrate wafer, and wherein the lower cavity extends from the dielectric layer to the buried oxide layer.

4. The method for integrating a crystal resonator with a control circuit according to claim 1, wherein the formation of the piezoelectric vibrator comprises:
forming the bottom electrode at a predetermined position on a surface of the device wafer; bonding the piezoelectric crystal to the bottom electrode; and forming the top electrode on the piezoelectric crystal;
or
forming the top electrode and the bottom electrode of the piezoelectric vibrator on the piezoelectric crystal; and bonding the top electrode, the piezoelectric crystal and the bottom electrode as a whole to the device wafer.

5. (canceled)

6. The method for integrating a crystal resonator with a control circuit according to claim 1, wherein the control circuit comprises a first interconnecting structure and a second interconnecting structure, and the first connecting structure comprises a first connecting member and a second connecting member,
wherein the first connecting member is connected to the first interconnecting structure and the bottom electrode of the piezoelectric vibrator, and the second connecting member is connected to the second interconnecting structure and the top electrode of the piezoelectric vibrator.

7. The method for integrating a crystal resonator with a control circuit according to claim 6, wherein the bottom electrode is formed on a surface of the device wafer and extends beyond the piezoelectric crystal thereunder to come into electrical connection with the first interconnecting structure, and the extension of the bottom electrode beyond the piezoelectric crystal constitutes the first connecting member.

8. The method for integrating a crystal resonator with a control circuit according to claim 6, wherein the first connecting member is formed on the device wafer prior to the formation of the bottom electrode so as to be electrically connected to the first interconnecting structure and brought into electrical connection with the bottom electrode subsequently formed on the device wafer; wherein the first connecting member comprises a rewiring layer connected to the first interconnecting structure.

9. (canceled)

10. The method for integrating a crystal resonator with a control circuit according to claim 6, wherein the formation of the second connecting member comprises:
forming an encapsulation layer on the device wafer;
forming a through hole in the encapsulation layer and filling a conductive material in the through hole, to form a conductive plug having a bottom portion electrically connected to the second interconnecting structure and a top portion exposed from the encapsulation layer;
forming the top electrode which extends beyond the piezoelectric crystal to the top portion of the conductive plug to bring the top electrode into electrical connection with the conductive plug, or forming the top electrode, then forming an interconnecting wire on the encapsulation layer, the interconnecting wire having one end covering the top electrode and a further end covering the conductive plug; and
removing the encapsulation layer.

11. The method for integrating a crystal resonator with a control circuit according to claim 1, wherein the formation of the cap layer delimiting the upper cavity comprises:
forming a sacrificial layer on a surface of the device wafer to cover the piezoelectric vibrator;
forming a cap material layer over the surface of the device wafer to warp the sacrificial layer by covering top and side surfaces of the sacrificial layer;
forming at least one opening in the cap material layer to form the cap layer, and removing the sacrificial layer via the opening in which the sacrificial layer is exposed so as to form the upper cavity; and
closing the opening in the cap layer to close the upper cavity and enclose the piezoelectric vibrator within the upper cavity.

12. (canceled)

13. The method for integrating a crystal resonator with a control circuit according to claim 1, wherein the formation of the second connecting structure comprises:
forming a contact pad on the surface of the device wafer, the contact pad having a bottom electrically connected to the control circuit and a top configured for electrical connection to the semiconductor die.

14. The method for integrating a crystal resonator with a control circuit according to claim 1, further comprising, subsequent to the bonding of the semiconductor die,
forming an encapsulation layer over the device wafer to cover both the semiconductor die and an external surface of the cap layer outside the upper cavity.

15. An integrated structure of a crystal resonator and a control circuit, comprising:
a device wafer in which the control circuit and a lower cavity are formed, wherein the lower cavity is exposed at a front side of the device wafer;
a piezoelectric vibrator comprising a top electrode, a piezoelectric crystal and a bottom electrode, wherein the piezoelectric vibrator is formed on the front side of the device wafer above the lower cavity;
a first connecting structure configured to electrically connect the top electrode and the bottom electrode of the piezoelectric vibrator to the control circuit; and
a cap layer which is formed on the front side of the device wafer and covers the piezoelectric vibrator, wherein the cap layer together with the piezoelectric vibrator and the device wafer delimits an upper cavity;
a semiconductor die, bonded to the front side of the device wafer; and
a second connecting structure configured to electrically connect the semiconductor die to the control circuit.

16. The integrated structure of a crystal resonator and a control circuit according to claim 15, wherein the device wafer comprises a substrate wafer and a dielectric layer formed on the substrate wafer, and wherein the lower cavity is formed in the dielectric layer.

17. The integrated structure of a crystal resonator and a control circuit according to claim 16, wherein the substrate wafer is a silicon-on-insulator substrate comprising a base layer, a buried oxide layer and a top silicon layer, which are sequentially stacked from a back side to the front side of the substrate wafer, and wherein the lower cavity extends from the dielectric layer to the buried oxide layer.

18. The integrated structure of a crystal resonator and a control circuit according to claim 15, wherein the control circuit comprises a first interconnecting structure and a second interconnecting structure, and the first connecting structure comprises a first connecting member and a second connecting member,
wherein the first connecting member is connected to the first interconnecting structure and the bottom electrode of the piezoelectric vibrator, and the second connecting member is connected to the second interconnecting structure and the top electrode of the piezoelectric vibrator.

19. The integrated structure of a crystal resonator and a control circuit according to claim 18, wherein the bottom electrode is formed on a surface of the device wafer and extends beyond the piezoelectric crystal thereunder to come into electrical connection with the first interconnecting structure, and the extension of the bottom electrode beyond the piezoelectric crystal constitutes the first connecting member.

20. The integrated structure of a crystal resonator and a control circuit according to claim 18,
wherein the second connecting member comprises a conductive plug having an end electrically connected to the top electrode and a further end electrically connected to the second interconnecting structure;
or
wherein the second connecting member comprises:
a conductive plug which is formed on a surface of the device wafer and has a bottom portion connected to the second interconnecting structure; and
an interconnecting wire which has an end covering the top electrode and a further end covering a top portion of the conductive plug, so that the interconnecting wire comes into connection with the conductive plug.

21. (canceled)

22. The integrated structure of a crystal resonator and a control circuit according to claim 15, wherein the second connecting structure comprises a contact pad formed on the surface of the device wafer, the contact pad having a bottom electrically connected to the control circuit and a top configured for electrical connection to the semiconductor die.

23. The integrated structure of a crystal resonator and a control circuit according to claim 15, wherein at least one opening in which a closure plug is fitted for closing the upper cavity is formed in a portion of the cap layer that is in positional correspondence with the upper cavity.

24. The integrated structure of a crystal resonator and a control circuit claim 15, further comprising:
an encapsulation layer that is formed on the device wafer and covers both the semiconductor die and an external surface of the cap layer outside the upper cavity.
